(19) United States
(12) Patent Application Publication
(10) Pub. No.: US 2008/0074142 A1
(43) Pub. Date: Mar. 27, 2008

(54) Routing for Microprocessor Busses

(76) Inventor: Alex Henderson, Portola Valley, CA (US)

Correspondence Address: STEVEN A. NIELSEN;ALLMAN & NIELSEN, P.C, 100 Larkspur Landing Circle, Suite 212, LARKSPUR, CA, 94939, US

(21) Appl. No.: 11/534,754

(22) Filed: Sep. 25, 2006

(51) Int. Cl. H03K 19/177

(52) U.S. Cl. 326/41

(57) ABSTRACT

This invention provides means and methods for improving the routing and multiplexing logic of microprocessor busses and other similar high fan logic functions in FPGA and ASIC circuits. Routing of high fan-in signals is simplified by distributing the multiplexing function. The multiplexing function is separated into an AND function in the logic block and a programmable OR function in the routing block. Programming bits control which signals are ORed together in the routing elements. The AND output of a peripheral is controlled by either a distributed control circuit or by control signal(s) from a centralized control circuit.

### CROSS-REFERENCE TO RELATED APPLICATIONS

Not Applicable.

### BACKGROUND OF THE INVENTION

(1) Field of the Invention

The invention relates to programmable logic devices such as Field Programmable Gate Arrays (FPGA) and in particular, means and methods for improved routing of microprocessor busses.

Overview

Field Programmable Gate Arrays (FPGA) are configurable logic devices that can be tailored to a specific application. The configuration information may be stored in RAM bits, a persistent storage technology such as Flash memory bits, or a PROM technology such as fuses.

FIG. 1 is a simplified block diagram that illustrates the difference between an FPGA and other programmable logic devices known in the related art. FPGAs incorporate logic elements (101) and routing resources. In this example, the routing resources comprise output routing elements (102), wires (103), and input routing elements (104). The input routing elements (104) provide programmable connections between the wires and the inputs of the logic elements. The output routing elements (102) provide programmable connections between the outputs of the logic elements and the wires. By programming the logic elements, input routing elements, and output routing elements, it is possible to implement a variety of logic circuits. This makes an FPGA more like a gate array or structured ASIC than older programmable logic technologies e.g. PAL devices from MMI, AMD, National Semiconductor, and TI.

The simplified FPGA architecture in FIG. 1 has only vertical wires. In practice, both vertical and horizontal interconnections are required. FIG. 2 illustrates a more realistic implementation that incorporates horizontal wires (202) and programmable interconnect elements (201) in addition to the logic elements, input routing elements, output routing elements, and vertical wires in FIG. 1. The interconnect elements can be programmed to make a variety of connections between various horizontal (202) and vertical wires (203). U.S. Pat. No. 6,970,014 by Lewis describes a similar routing architecture that adds additional routing elements above and below the logic elements (101) that provide access to the horizontal wires (202).

FIG. 3 illustrates a simple implementation of a programmable interconnect element. In this example pass transistors (301) connect the horizontal wires (302) and vertical wires (303). The gates of the pass transistors are connected to programming bits.

FIG. 4 illustrates a multiplexer based programmable interconnect element (400). In this interconnect element multiplexers (401) connect vertical inputs (403) and horizontal inputs (404) to vertical outputs (405) and horizontal outputs (402).

The Multiplexer based programmable interconnect of FIG. 4 separates the input and output functions of the programmable interconnect and allows the programmable interconnect elements to function as repeaters or signal amplifiers. In deep sub-micron processes timing is dominated by interconnect delay. This has typically been addressed by “repeater insertion” in ASIC designs. FIG. 5 illustrates why repeaters improve timing.

In FIG. 5 input signal (500) is passed through a high drive strength driver (501). This driver drives a long wire. The resulting signal E at the input of receiver (502) has a very slow rise time as a result of the distributed RC circuit of the wire. As a result the output signal E is substantially delayed and has a large variation with process parameters and electrical conditions such as power supply voltages and noise from adjacent signals. If the wire is broken into segments using repeaters (503), (504) and (505) the rise time of the component signals is dramatically improved and the sensitivity to process, supply voltage and noise substantially reduced.

(2) Description of Related Art

Current State of the Art

The current state of the art in FPGAs is best illustrated by Xilinx Virtex V4 and Altera Stratix II devices.

Logic Elements

The logic elements in modern FPGAs typically contain programmable combinatorial logic functions, dedicated math functions, and registers.

FIG. 6 shows the structure of the logic elements of the Altera Stratix II FPGA. This logic function comprises a programmable combinatorial logic function with 8 inputs and two outputs, dedicated math functions (adders), and storage elements (registers)

Xilinx describes their logic element as a “Configurable Logic Block” or CLB. FIG. 7 shows the structure of a CLB.

The Xilinx CLB is divided into two “slices”. The combinatorial logic component is implemented as a 4 input RAM based lookup table or “LUT”. The LUTs can also be used as RAMs or shift registers. The registers can be configured as either flip-flops or latches.

Routing Resources

The routing resources in the Altera and Xilinx FPGAs are similar in construction. Xilinx routing resources are described in more detail to illustrate the current state of the art.

Routing Resources—XC3000

The Xilinx XC3000 routing architecture is based on a general purpose interconnect that consists of an array of short adjacent metal segments (803) oriented vertically and horizontally between the rows and columns of CLBs (801). This is illustrated in FIG. 8. The metal segments are interconnected by switch matrices (802).

The Xilinx CLBs (700) are connected to the general purpose interconnect via local routing (more metal segments) and Programmable Interconnect Points (1000). PIPs are individual switches that enable the connection between intersecting routing segments, or from routing segments to CLBs. PIPs are constructed from an array of six pass transistors (1001) as shown in FIG. 10. The switch matrices are also constructed using PIPs as illustrated in the same figure (201).

The Switch matrices (201) located at the intersections of the horizontal and vertical groups of general-purpose interconnect segments are also referred to In Xilinx publications as magic boxes. They provide a variety of possible interconnections between various pins on a switch matrix.

Routing resources are also used to connect CLBs (801) to Input Output or “I/O” circuitry (1101). PIPs (1102) are used to make programmable interconnections to the I/O circuitry. The I/O circuitry in state of the art FPGAs is much more complex than what is shown in FIG. 11. The Xilinx Virtex 4 parts include programmable delay elements Double Data Rate or “DDR” input and output registers and SERializer/DESeralizer or “SERDES” functions.

Routing Resources—V2-Pro

The routing resources in the Xilinx Virtex V2Pro and Virtex 4 FPGAs are structured hierarchically i.e. there are multiple types of wires or metal segments that connect to switch matrices skipping various numbers of rows and columns. These include:
Wires that connect to adjacent CLBs “direct connections” (1201)
Wires that connect to switch matrices one or two rows/columns distant “double lines” (1301)
Wires that connect to switch matrices 3 or 6 columns away “hex lines” (1401)
Wires that span the entire chip “long lines” (1501)

According to Xilinx the hierarchical structure allows, “Place-and-route software takes advantage of this regular array to deliver optimum system performance and fast compile times. The segmented routing resources are essential to guarantee IP cores portability and to efficiently handle an incremental design flow that is based on modular implementations. Total design time is reduced due to fewer and shorter design iterations.”

The Xilinx V2Pro has “fast interconnect” signals that directly connect adjacent “Direct connections” connect to CLB to the adjacent CLBs as shown in FIG. 13.

“Double Lines” route signals to the CLBs one or two rows of columns away as shown in FIG. 14.

The V2Pro also has “hex lines” that route signals vertically and horizontally to the CLBs 3 and 6 rows or columns away and “long lines that span the entire chip.

The Xilinx V2Pro also has some specialized routing designed to simplify interconnecting CLBs specialized functions. These include dedicated connections for:
Interconnecting the shift in and shift out signals of the LUTs with in a CLB when they are used in shift register mode.
Vertical interconnects between CLBs for carry and multiplexer functions.
Horizontal bi-directional busses (Xilinx attempt to solve the bussing problem).
Global clock signals distributed via balanced clock trees.

Routing Resources—Virtex-4

According to the Xilinx V4 Data Sheet “The general routing matrix (GRM) provides an array of routing switches between each component. Each programmable element is tied to a switch matrix, allowing multiple connections to the general routing matrix. The overall programmable interconnection is hierarchical and designed to support high-speed designs. All programmable elements, including the routing resources, are controlled by values stored in static memory cells. These values are loaded in the memory cells during configuration and can be reloaded to change the functions of the programmable elements.”

In fact, the Xilinx Vittex 4 FPGAs have a routing structure almost identical to the V2 Pro FPGAs comprising single, double, hex, and long lines in the vertical and horizontal directions.

The Virtex-4 FPGAs also have dedicated routing resources for specialized functions such as clock distribution and connecting SERDES to I/O pins. These include:
Eight global clock networks per quadrant that enables global and local clock distribution.
Four segmented horizontal 3-state lines per row for multiple on-chip buses per row.
Two vertical carry chains per every CLB slice.
One horizontal sum-of-products chain per CLB slice row for wide input functions with adjacent CLB slices.
One vertical “SRL16” chain per CLB to interconnect multiple SRL16s to build deep pipeline registers. The SRL16 refers to a Xilinx CLB feature that allows the programming circuitry in the CLB be used as a programmable length shift register up to 16 bits long.

Memory Resources

Current state of the art FPGAs incorporate multiple types of RAM. The RAMs can be configured to provide features such as various word widths, single and dual port operation, and input and output registers. The Xilinx and Altera FPGAs differ slightly in their RAM resources.

Altera “Trimatrix” RAM

The following segment of the Altera Stratix II data sheet describes the RAM resources of these parts:

“Altera provides 512 bit, 4 k bit, and 512 k bit RAM blocks in the Stratix 11 FPGAs. These RAMs can be configured in a large variety of organizations (word widths). The 512 bit RAMs can be configured as 512 words by 1 bit, 256 words by 2 bits, 128 words by 4 bits, 64 words by 8 or 9 bits, 32 words by 16 or 18 bits. The 4 k bit RAMs can be configured as 4 k words by 1 bit, 2 k words by 2 bit, 1 k words by 4 bit, 512 words by 8 or 9 bits, 256 words by 16 or 18 bits, 256 words by 32 or 36 bits. The 512 k bit RAMs can be configured as 64 k words by 8 or 9 bits, 32 k words by 16 or 18 bits, 16 k words by 32 or 36 bits, 8 k words by 64 or 72 bits, 4 k words by 128 or 144 bits. In the wider modes (8 or 9 bits and wider) independent byte enables are supported. The byte enables control writing of subsections of the configured word width. For example if the 512 bit RAM is configured in 32 word by 16 bit mode the byte enable signals control writing of the lower and upper 8 bits of the 16 bit word independently.

The Altera RAMs also offer a variety of modes including:
Single port mode—this mode supports a single read/write interface.
Register file or “simple dual port mode”—this mode supports one read interface and one write interface that can be used simultaneously.
Dual port mode—this mode supports two independent read write interfaces.
Shift register mode.
ROM mode.
FIFO mode.

All Stratix II memory blocks support the shift register mode. Embedded memory block configurations can implement shift registers for digital signal processing (DSP) applications, such as finite impulse response (FIR) filters, pseudo-random number generators, multi-channel filtering, and auto-correlation and cross-correlation functions. These and other DSP applications require local data storage, traditionally implemented with standard flip-flops that quickly exhaust many logic cells for large shift registers. A more efficient alternative is to use embedded memory as a shift-register block, which saves logic cell and routing resources.

ROM Mode

M512 and M4K memory blocks support ROM mode. A memory initialization file (.mif) initializes the ROM contents of these blocks. The address lines of the ROM are registered. The outputs can be registered or unregistered. The ROM read operation is identical to the read operation in the single-port RAM configuration.

FIFO Buffers Mode

TriMatrix memory blocks support the FIFO mode. M512 memory blocks are ideal for designs with many shallow FIFO buffers. All memory configurations have synchronous inputs; however, the FIFO buffer outputs are always combinational. Simultaneous read and write from an empty FIFO buffer is not supported. Refer to the Single- & Dual-Clock FIFO Megafunctions User Guide and the FIFO Partitioner Megafunction User Guide by Altera for more information on FIFO buffers.

Xilinx Virtex-4 RAM

The Xilinx Virtex 4 FPGAs incorporate two types of RAM resources. These are 8 k bit “block RAMs”, and “distributed RAM”. The block RAMs are dedicated RAM blocks similar to the Altera RAMs. They can be configured as single or dual port 8 k word by 1 bit, 4 k word by 2 bits, 4 k word by 4 bits, 1 k word by 8 or 9 bits, 512 word by 16 or 18 bits, and 256 by 32 or 36 bits. The Xilinx block rams offer the same variety of configuration modes at the Altera RAMS. The Xilinx RAMs on the Virtex V4 FPGAs also incorporate dedicated counter logic for FIFO modes.

Xilinx Distributed RAMs are actually an configurable mode of the logic elements that allows the used to configure the logic elements as small RAMs i.e. access the RAM control signals of the lookup tables used for the combinatorial function generators.

The Impact of Incorporating Processors

Newer FPGAs incorporate microprocessors (1601) as either “hard macros” (an actual microprocessor with connections to the FPGA routing resources) or “soft cores” (microprocessors implemented using the FPGA logic cells). FPGA designs that use these microprocessors must connect the microprocessors to peripherals e.g. memories and registers (1502).

FPGA vendors typically provide a collection of peripherals such as on chip memories, memory controllers for use with off chip memories, communications controllers, graphics interfaces, and the like for use with their microprocessors. The microprocessor interacts with these peripherals by reading and writing registers in the peripherals. In some cases, the peripherals may directly access other peripherals or memories via Direct Memory Access or “DMA”. These peripherals may be provided as “soft cores” that are implemented using the logic and routing resources of the FPGA or as “hard cores” that are implemented by a dedicated function on the FPGA. On their latest FPGA, Xilinx provides an Ethernet controller that is implemented as a hybrid hard/soft core. The Media Access Controller portion of this core is a hard core and the interface to the microprocessor bus is a soft core.

The interconnections between microprocessors and peripherals typically take the form of a “bus” as shown in FIG. 2 in U.S. Pat. No. 6,973,524 entitled Interface for bus independent core, by Solomon, is representative of these microprocessor busses. The Address decode function (1603) decodes ranges of addresses used by each peripheral and generates a “chip select” signal to signal the peripheral that the microprocessor is trying to communicate with it. The various FPGA vendors have standardized on different internal microprocessor buses. Xilinx uses the On-chip Peripheral Bus (OPB) and Processor Local Bus (PLB) bus defined by IBM as part of the PowerPC architecture. Altera uses the “AMBA” bus.

Implementing Bus Connections in an FPGA

FIG. 17 illustrates a simple connection of a microprocessor to a number of peripherals. In this example, the microprocessor bus is composed of unidirectional address and control pins and a bi-directional data interface. Since they have a single source and many destinations “high fan-out” the unidirectional signals can be implemented simply in the current FPGA architectures.

The bi-directional data interface can be implemented as separate data input and data output connections (1701) as shown in FIG. 17 or as shared input/output signals using a technique like “tri-state drivers” or a wired AND function. These shared signal techniques require more complex drivers and special circuits like “active pull-ups” and “bus keepers”. As a result the shared input/output implementation has fallen out of favor in FPGA and ASIC designs.

FIG. 17 also illustrates the use of distributed bus control circuitry including address decoding.

Data Input Implemented Using Multiplexers

High fan-in nets like the data input of a microprocessor can be implemented using multiplexers (1504) as shown in FIG. 18. In FIG. 18 the data input function is implemented as a chain of two to one multiplexers (1504) with a simple control circuit (1503) implemented as part of the bus control circuitry.

The control circuit decodes (1503) the address and control signals to ensure that the data from the correct peripheral is passed to the microprocessor. This logic can be the same logic that generated control signals for write operations.

The implementation shown in FIG. 18 does not perform well for large numbers of inputs. The serial chain of multiplexers limits the maximum speed of this implementation. Most state of the art ASIC designs use a tree of wider multiplexers as shown in FIG. 19. FIG. 19 illustrates the use of 4 to 1 multiplexers with wider inputs (1901). This improves the performance by reducing the number of multiplexers that the (worst case) input signals must traverse. This performance comes at the cost of increased routing. In general, the wider the multiplexers used the shorter the logic delay for the input signals. Wider multiplexers however require more routing. In deep sub-micron designs where routing delay may exceed logic delays the small to medium sized multiplexers that can be implemented in a single FPGA CLB a good trade off between routing and logic delays.

In the Xilinx and Altera designs the multiplexers also consume logic resources. This also complicates the place and route process since the multiplexers must be placed in locations that have the least impact on timing and routing. Optimal placement of the multiplexers and generation of control signals for the multiplexers in a multiplexer tree can be very complicated. Place and route software must also swap pins between the multiplexers and change the control signals to ensure optimal routing.

Multiple Masters and DMA

Microprocessor systems that contain multiple “bus masters” or support Direct Memory Access (DMA) must provide a mechanism for devices other than the processor to drive the data output, address and control signals of the bus. This way a separate “bus master” can take control of the bus and perform a read, write, or other bus operation. When multiple bus masters are supported the logic for data output, address and control signals may have high fan in functions and require the same kind of multiplexing as the data input signals.

Routing of microprocessor, peripheral, and memory interconnections consumes a large portion of the routing resources and logic in FPGAs and structured ASIC devices. Accordingly, what is needed in the art is a new architecture that simplifies the routing of these interconnections.

### BRIEF SUMMARY OF THE INVENTION

To address the above-discussed deficiencies of the prior art, the present invention provides simplified routing of high fan-in signals by distributing the multiplexing function. The multiplexing function is separated into an AND function (2002) in the logic block and a programmable OR function (2001) in the routing block as shown in FIG. 20.

Programming bits (2002) control which signals are ORed together in the routing elements. The AND output of a peripheral is controlled by either a distributed control circuit as shown in FIG. 17 or by control signal(s) from a centralized control circuit. No control signals need to be routed to the OR function.

Logic Equivalents

While the invention is being described in terms of an AND function in the logic element and an OR function in the routing element one skilled in the art will recognize that many logically equivalent implementations exist including the use of an OR function in the logic element combined with an AND function in the routing element, and NAND or NOR functions in both the logic element and the routing element.

Better Routing of Input Signals of High Fan-In Functions

FIG. 21 illustrates the routing and logic element utilization required to implement a multiplexer tree in a conventional FPGA.

FIG. 22 illustrates why distributed multiplexers improve routing. In FIG. 22 the signals comprising the data in signal are routed as a single signal.

Because the signals are part of a high fan-in function the OR functions in the routing blocks where the signals join are turned on. This allows the many signals that make up a the high fan-in OR in a large multiplexer to be routed using only the resources required for a single signal.

### BRIEF DESCRIPTION OF THE DRAWINGS

FIG. 1: is a simplified schematic block diagram of a typical FPGA architecture.

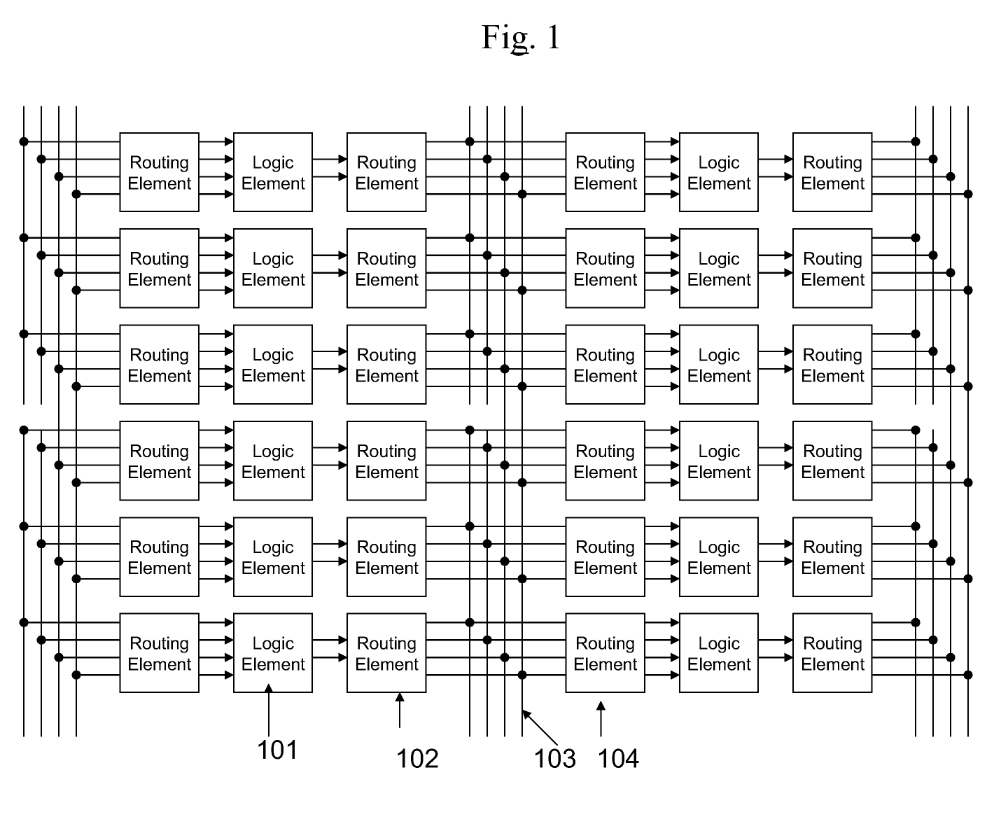

FIG. 2: Programmable Interconnect and Horizontal wires

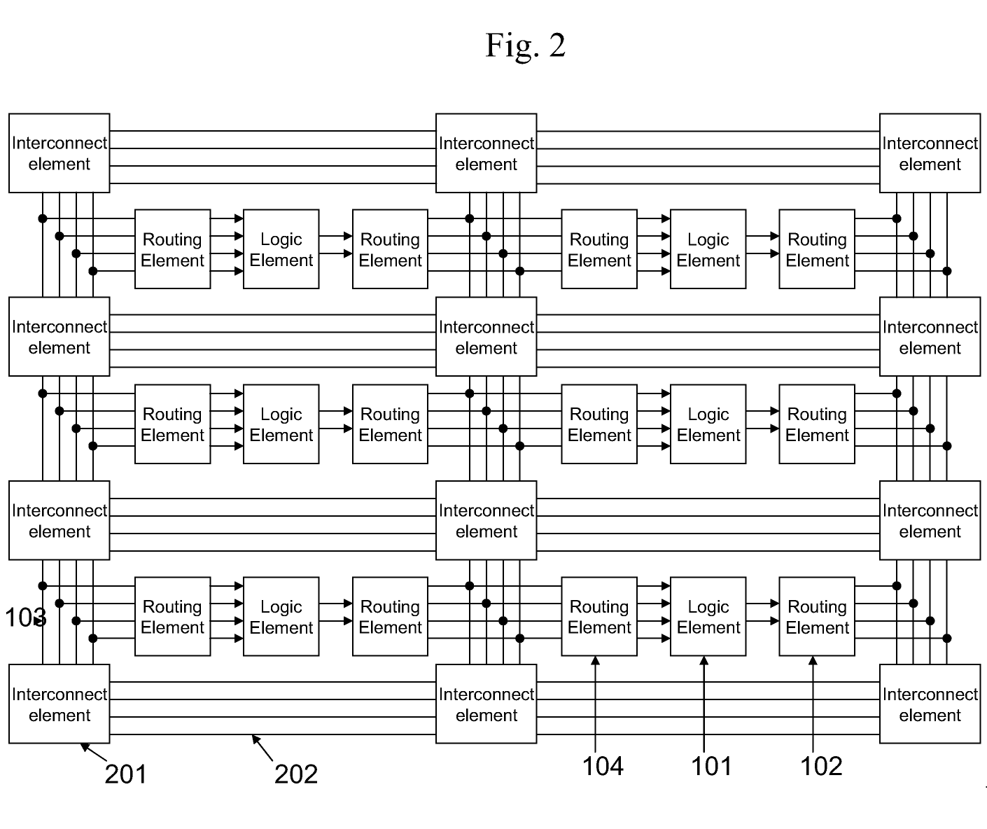

FIG. 3: A Simple Programmable Interconnect Element

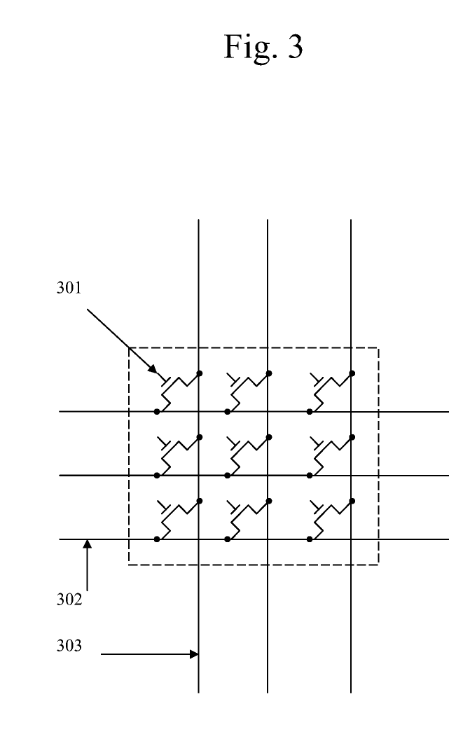

FIG. 4: A Multiplexer Based Programmable Interconnect

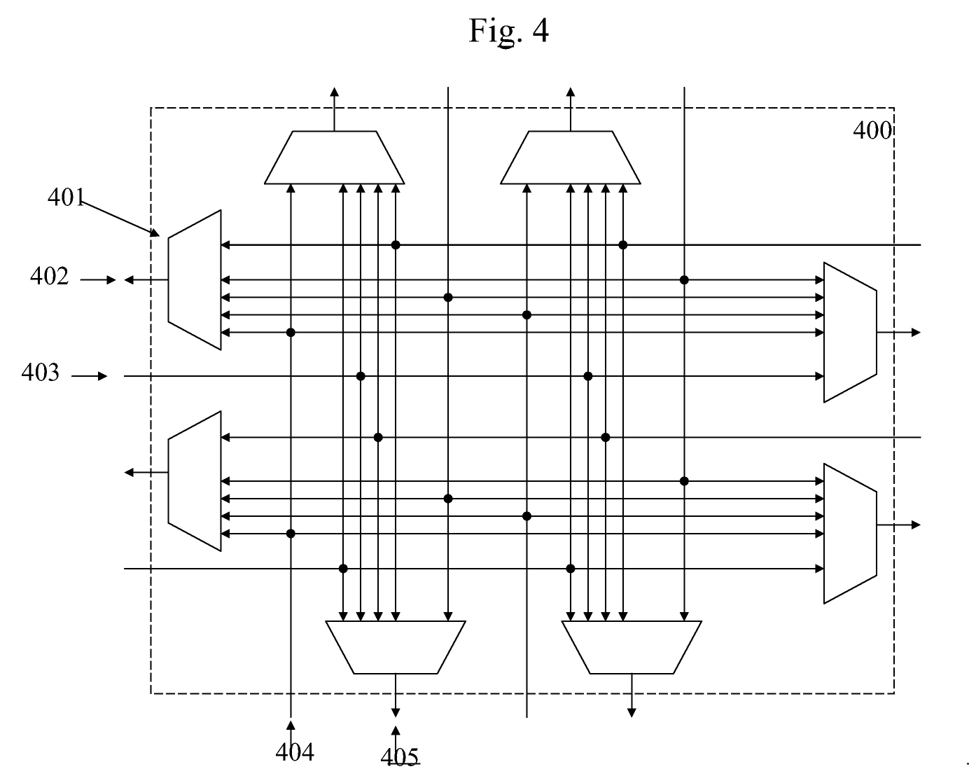

FIG. 5: Timing Improvement from Repeaters

FIG. 6: Altera Stratix Logic Function

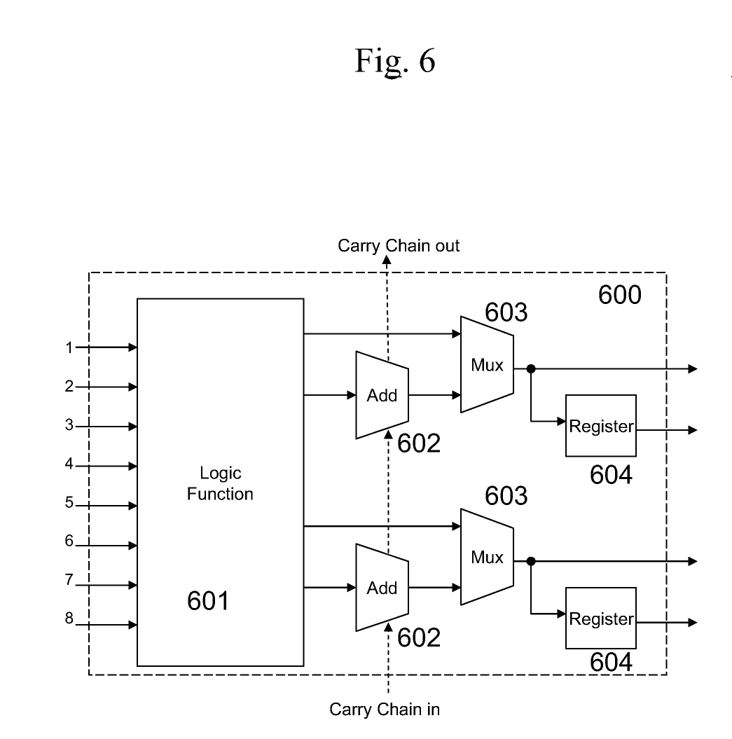

FIG. 7: The Xilinx CLB

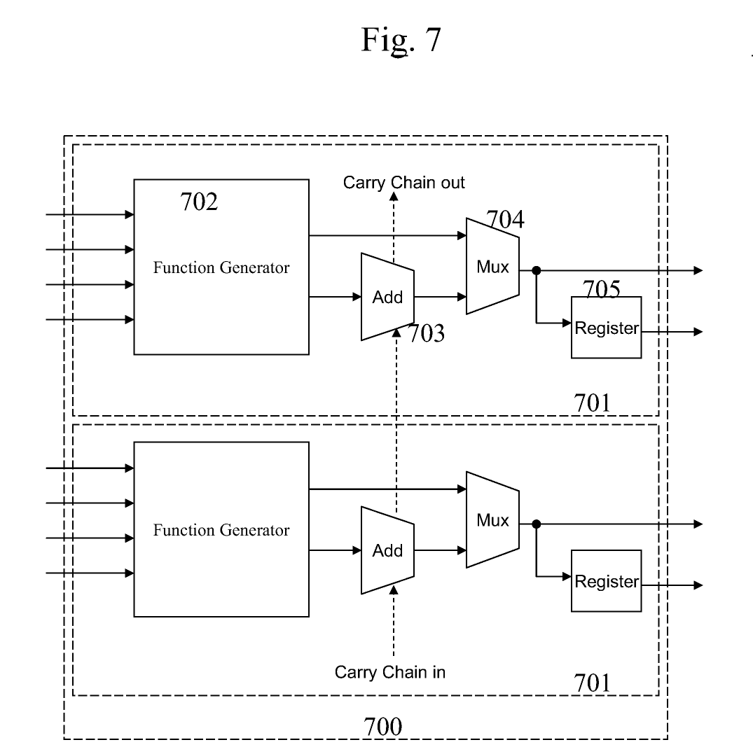

FIG. 8: Xilinx XC3000 Routing Resources

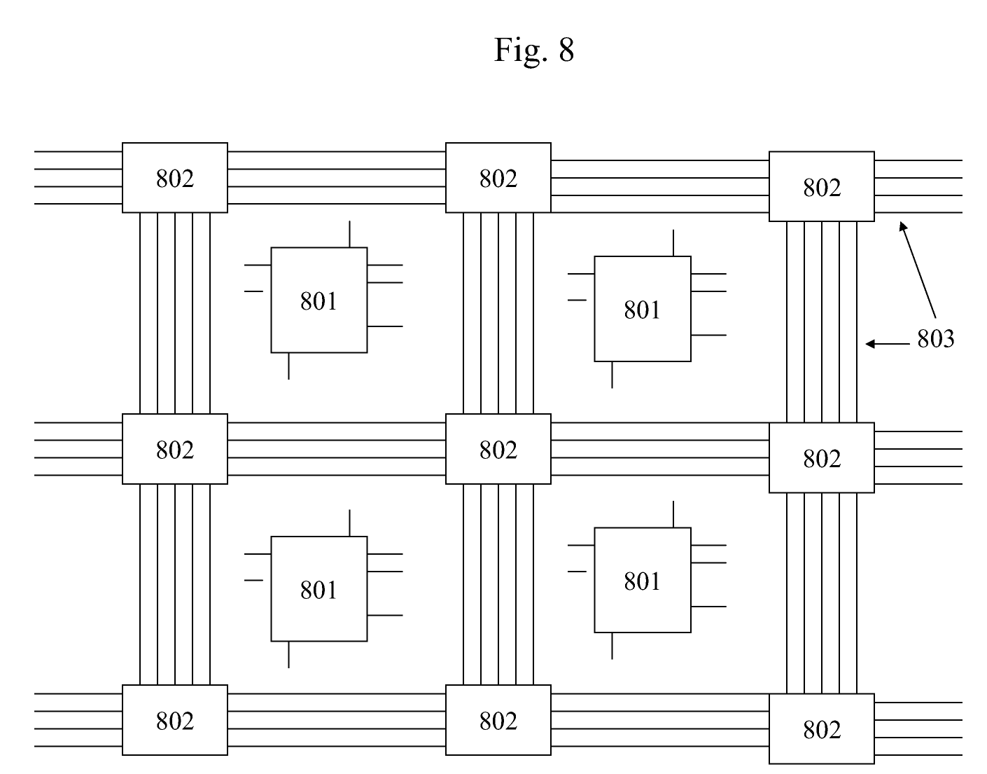

FIG. 9: Programmable Interconnect Points and Local Interconnections

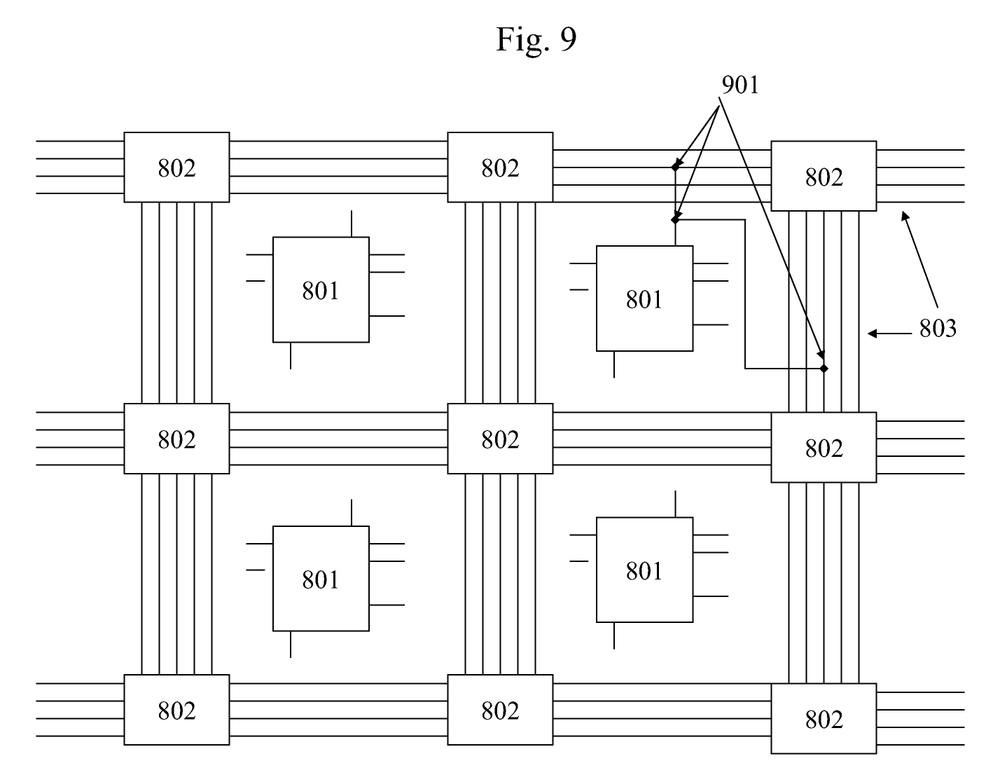

FIG. 10: Construction of Programmable Interconnect Points (PIPS) and Switch Matrices

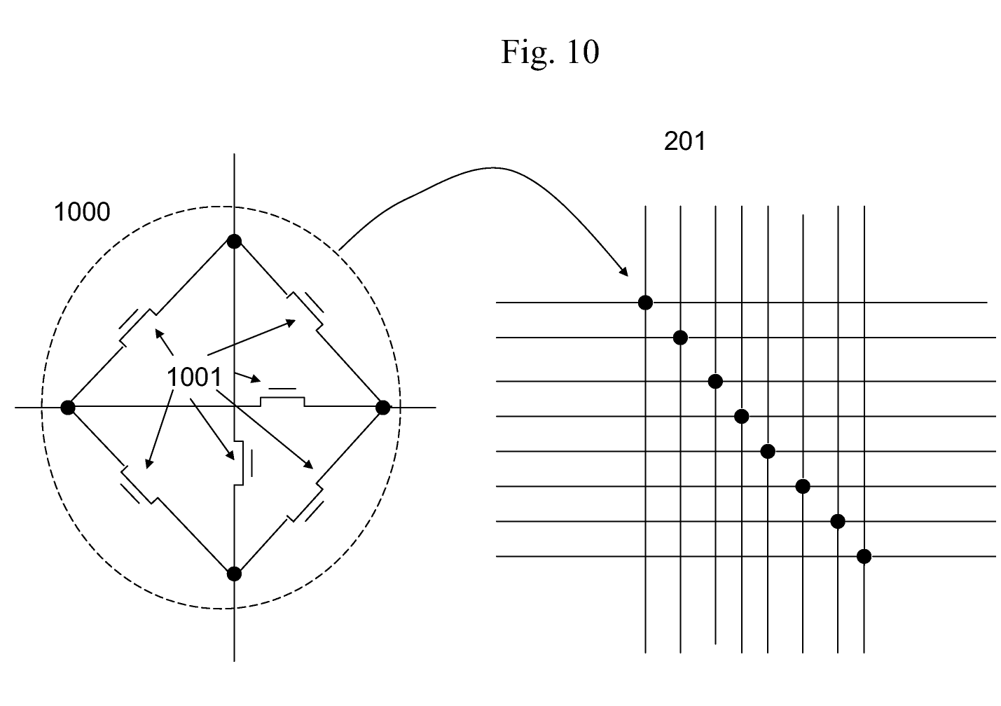

FIG. 11: I/O Routing

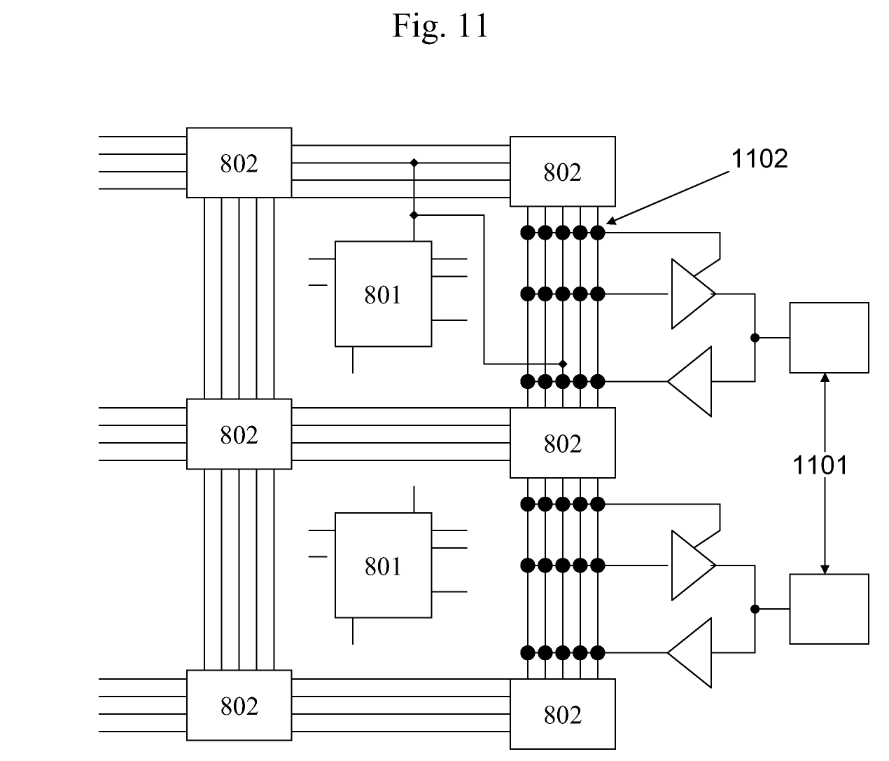

FIG. 12: Basic Xilinx V2Pro Routing

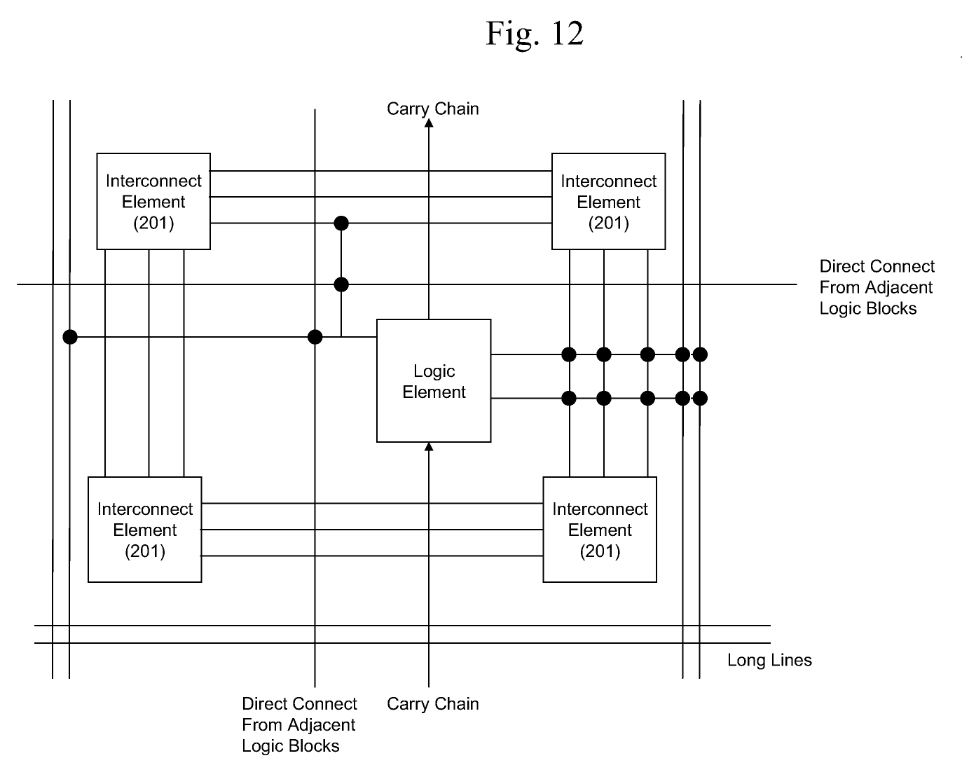

FIG. 13: Xilinx Direct Connections

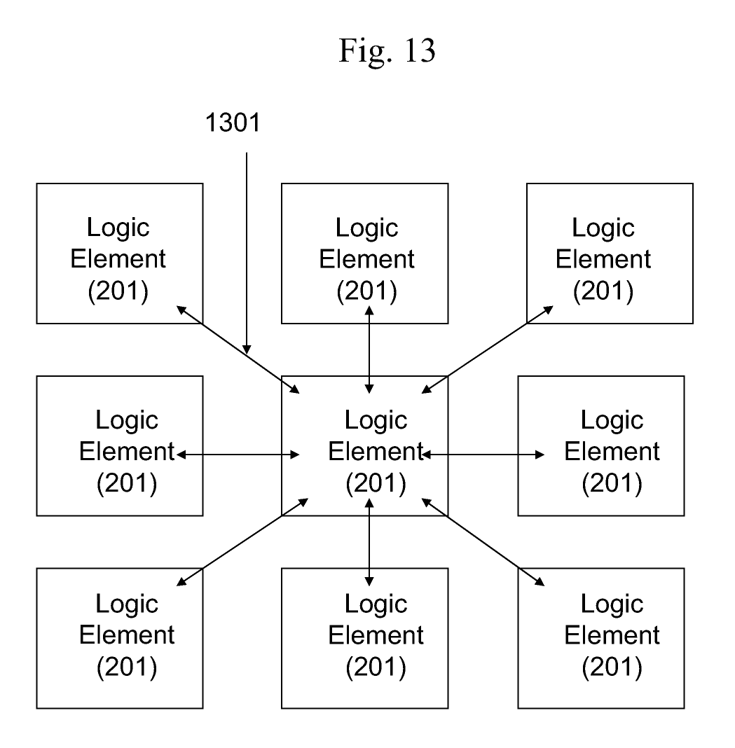

FIG. 14: Xilinx V2Pro double lines

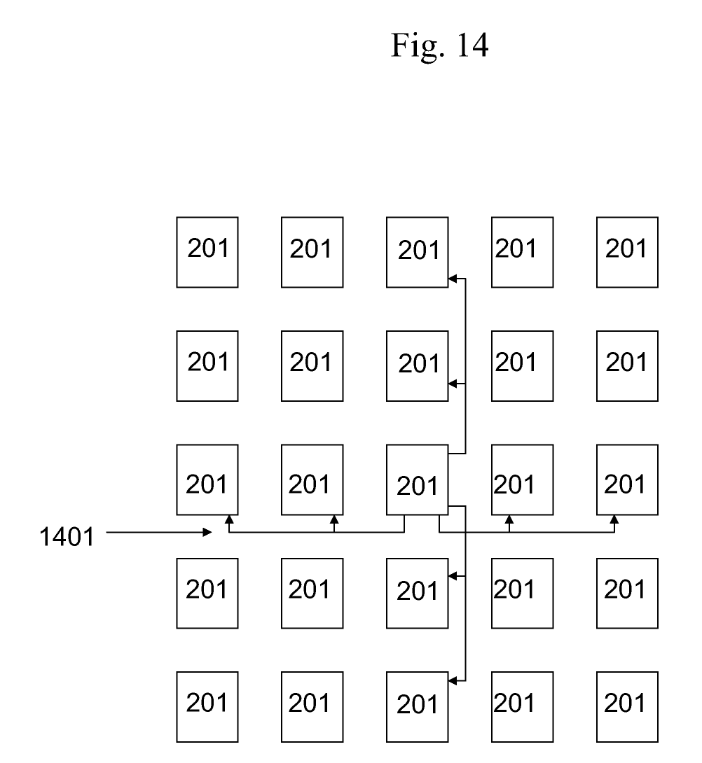

FIG. 15: Xilinx V2Pro “hex lines” and “long lines”

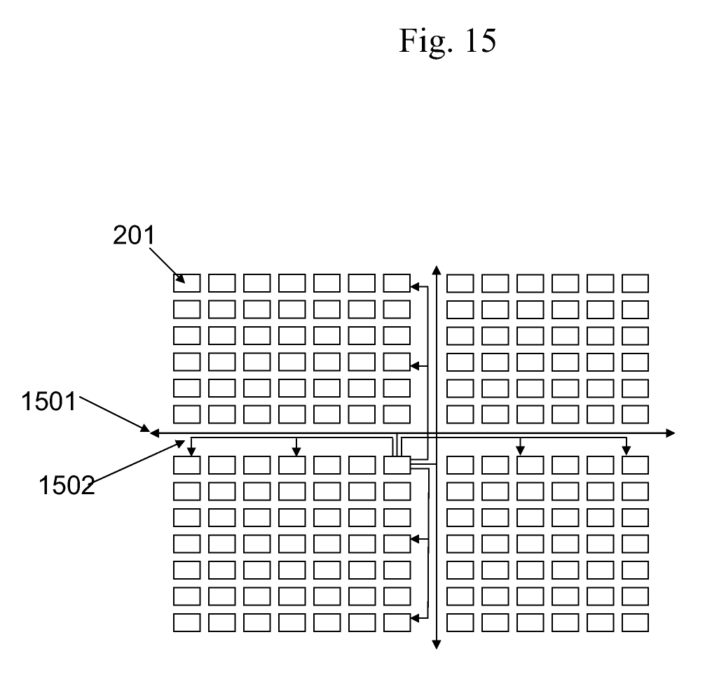

FIG. 16 Processor Connections

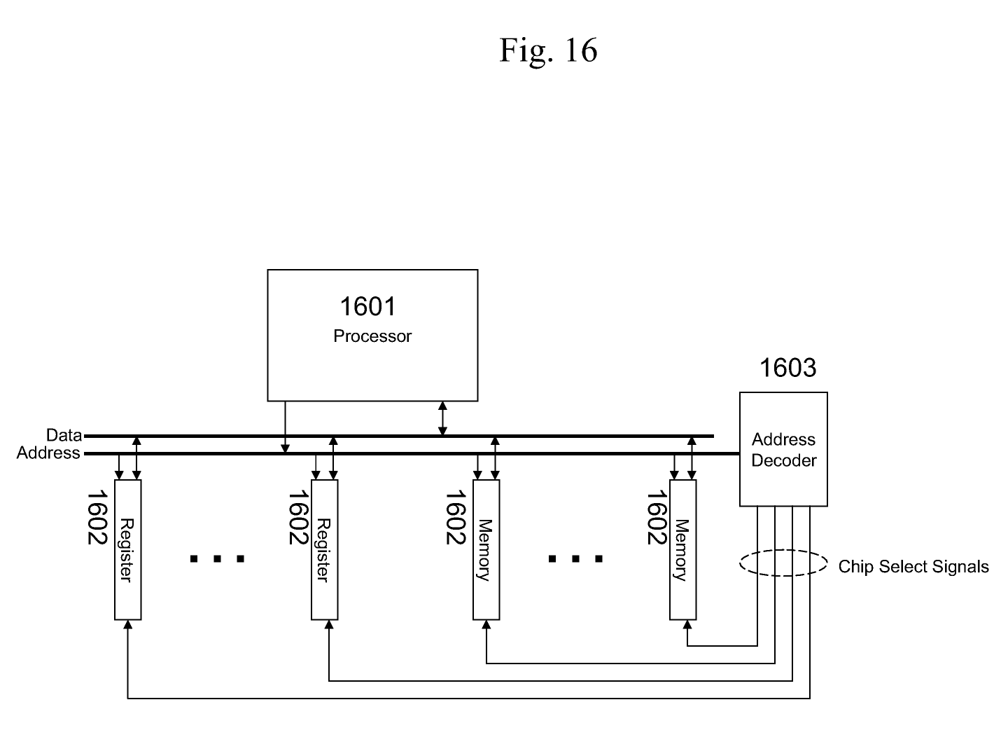

FIG. 17: A Simple Microprocessor Bus

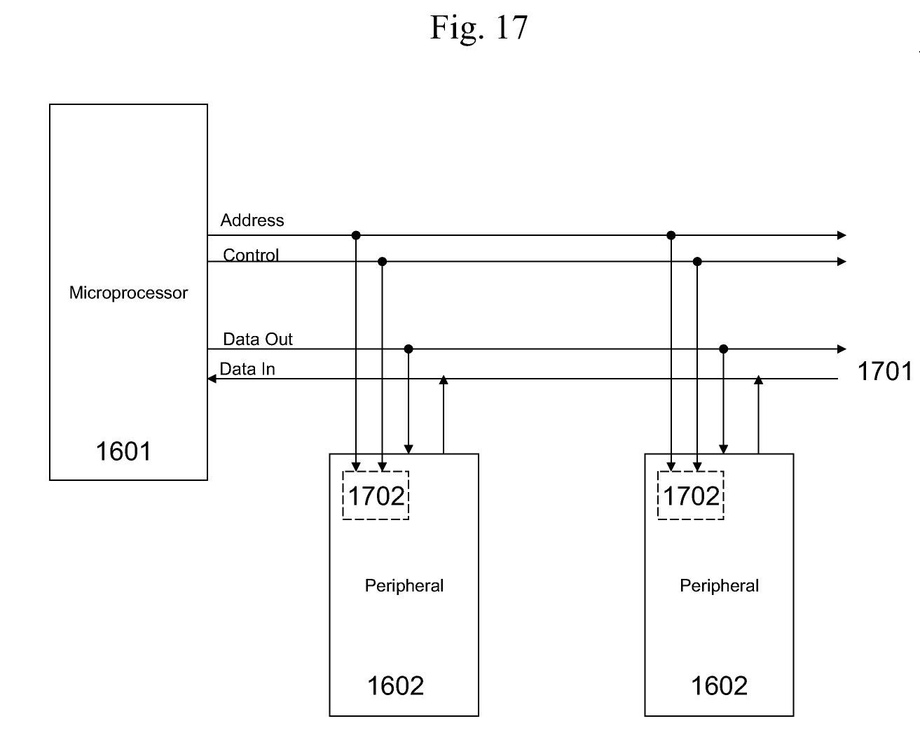

FIG. 18: Multiplexer for High Fan In signals

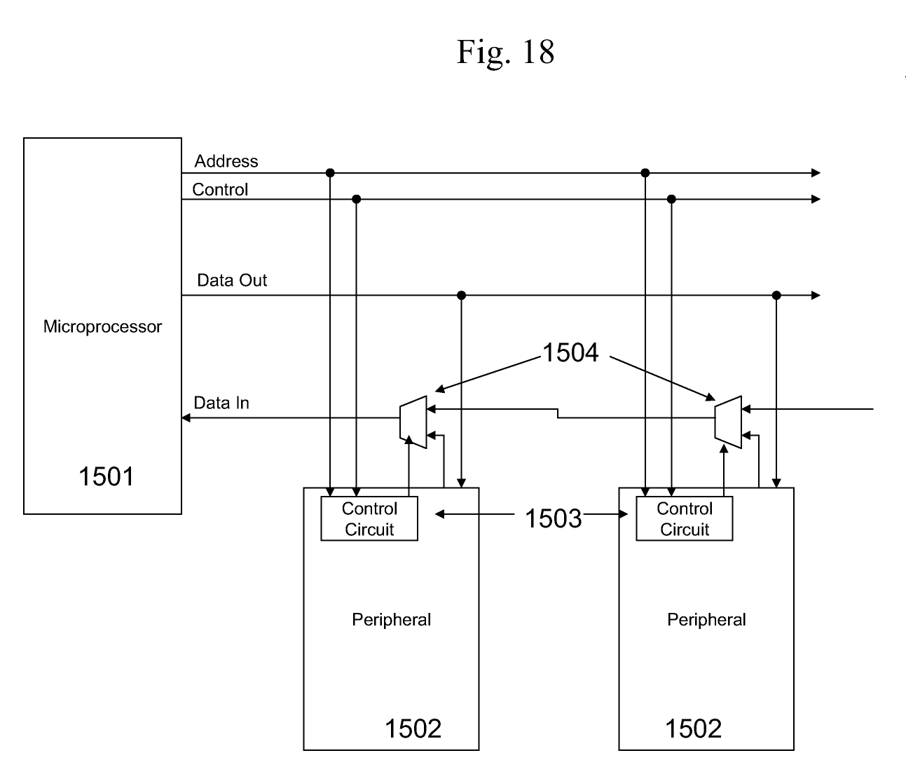

FIG. 19: Tree of 4 Input Multiplexers

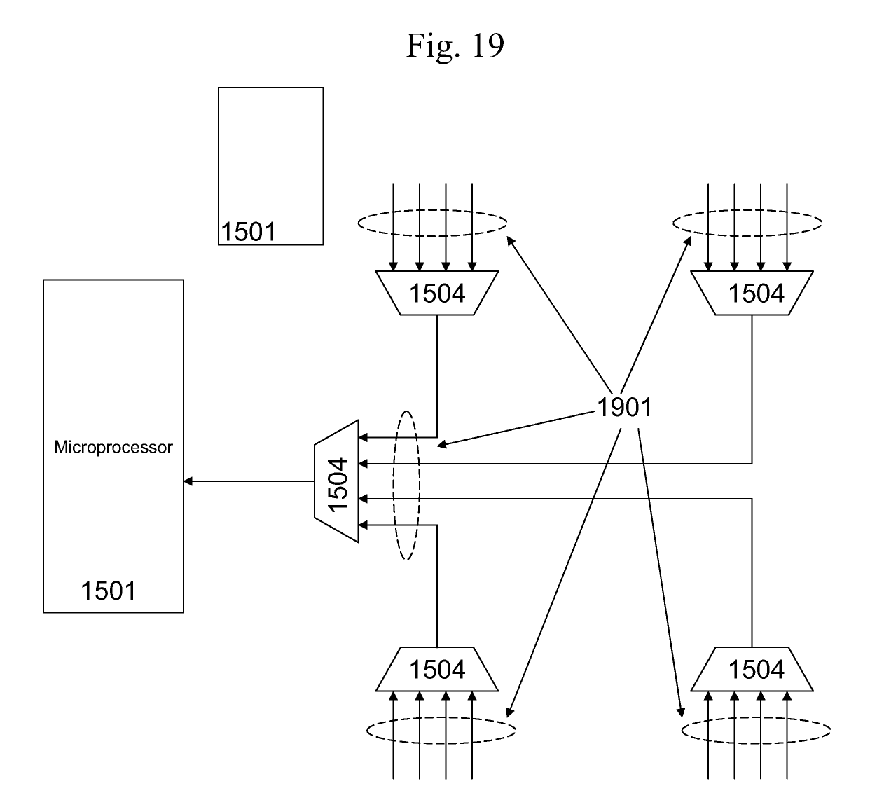

FIG. 20: Basic Embodiment of the Invention

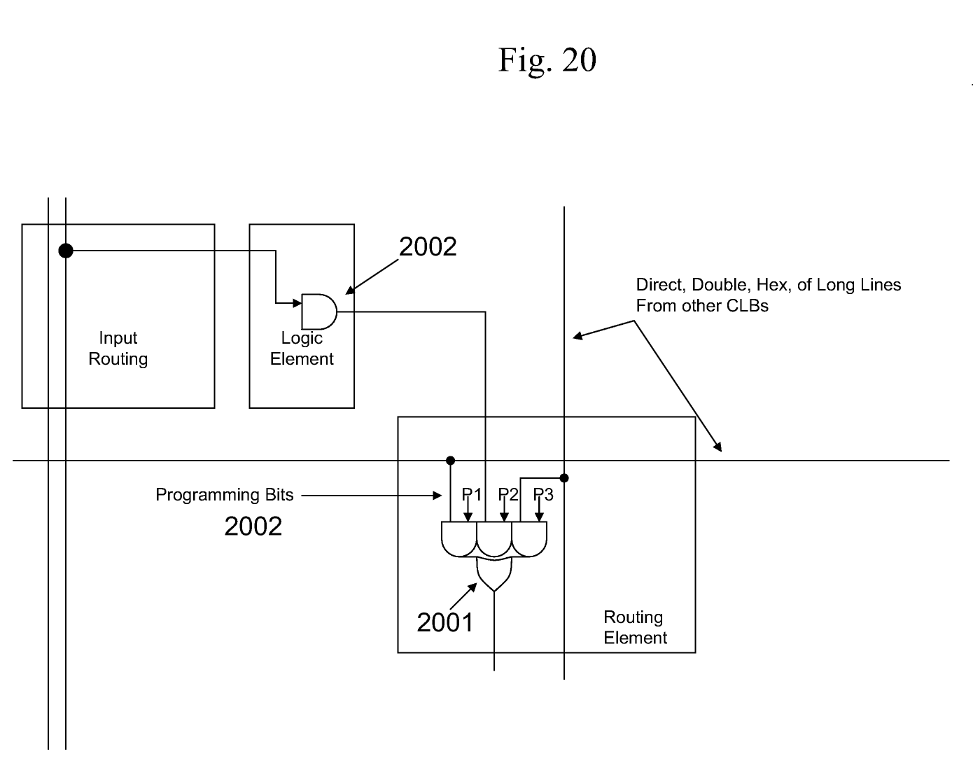

FIG. 21: Conventional Multiplexer Tree in an FPGA

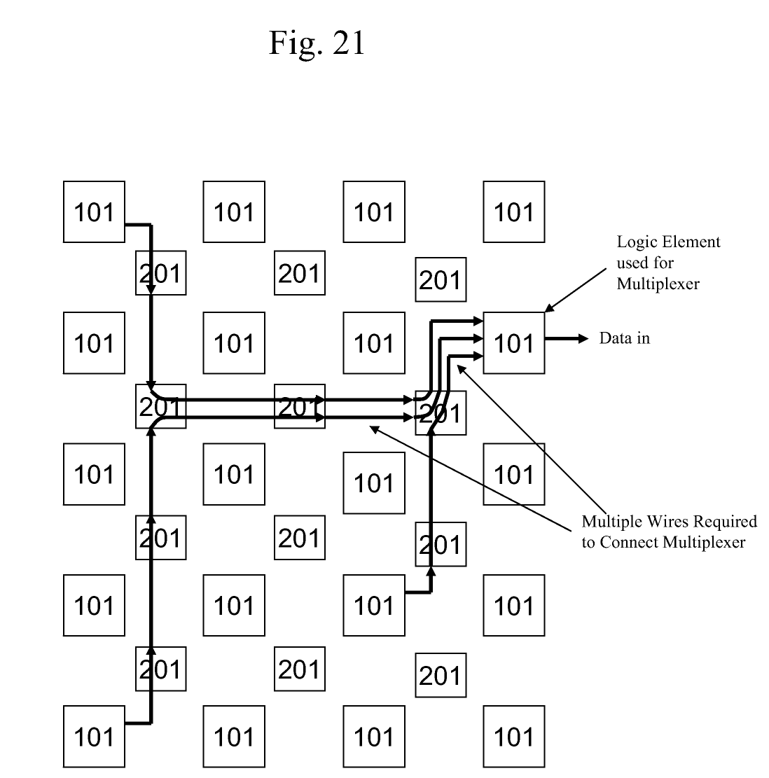

FIG. 22: Routing of Signals

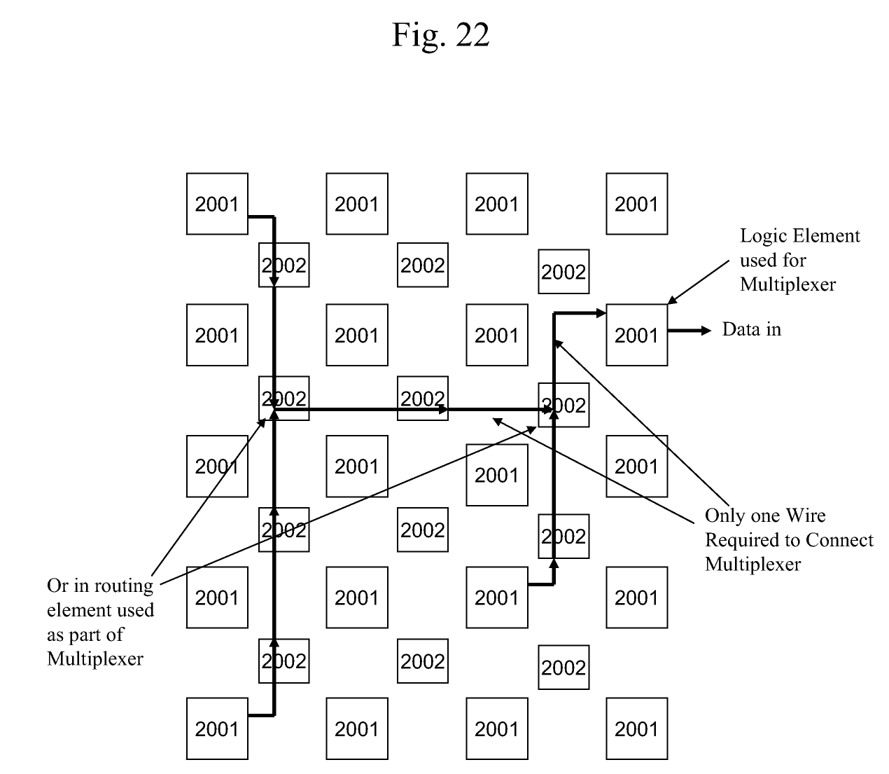

FIG. 23: The output AND function in a Xilinx like Logic Element

FIG. 24: Implementation of Routing Element

FIG. 25: RAM block with AND outputs

FIG. 26: Transfer Gated replaced by OR function with Repeaters

FIG. 27: An alternate embodiment incorporating the AND function in the output routing function

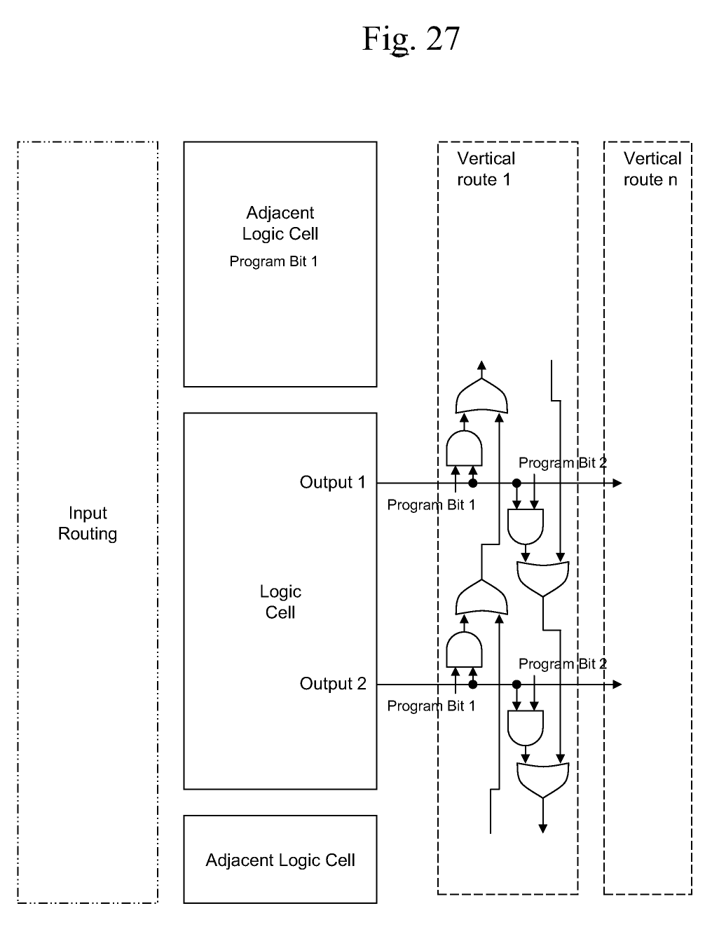

FIG. 28: Preferred Embodiment of a Microprocessor Peripheral in an FPGA

FIG. 29: Data Output Routing of Distributed RAM

FIG. 30: Logic Element Configuration for Efficient CAM Implementation

FIG. 31: Hierarchical Construction of a Large ASIC

FIG. 32: Routing Within a Hierarchical Block

### DETAILED DESCRIPTION OF THE INVENTION AND THE PREFERRED EMBODIMENT

The preferred embodiment of the invention comprises the addition of an AND element and buffer to the output of the logic element of an FPGA, a routing element that utilized unidirectional signals and incorporates an OR function, RAM blocks with AND elements and buffers for the output pins, and microprocessor(s) with AND elements and buffers for the output pins.

Logic Element

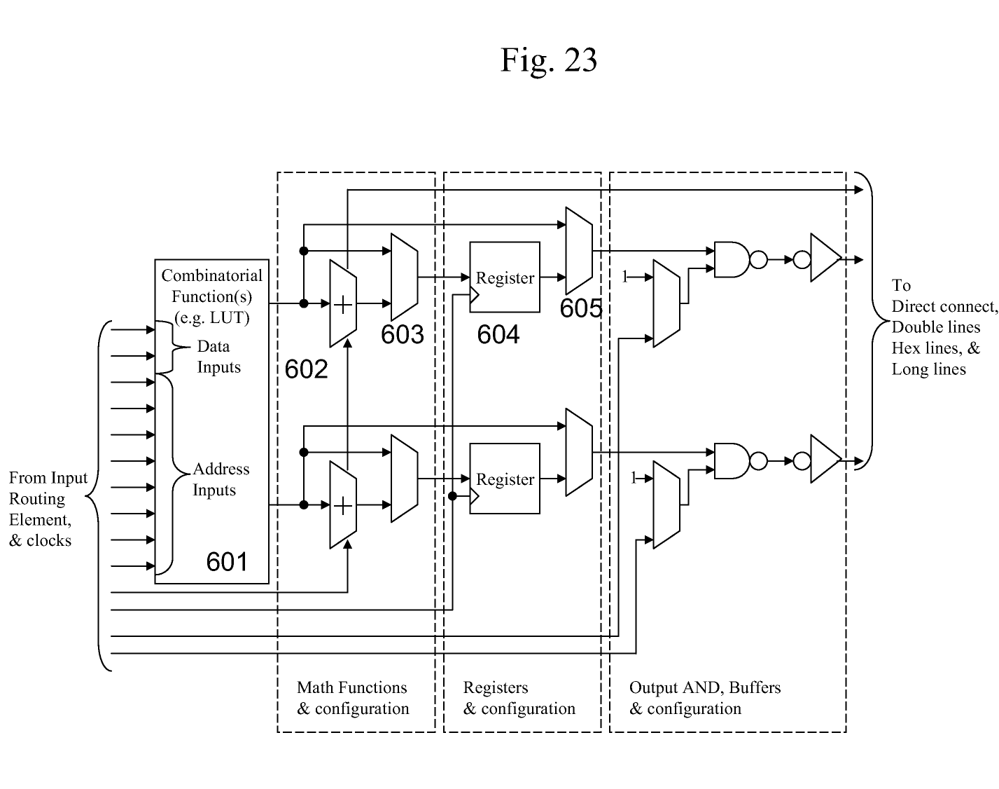

FIG. 23 illustrates the addition of an output AND function to a Xilinx like logic element in accordance with the present invention.

The AND function in the logic element acts as an enable or disable for the output signal when connected to the OR implemented in the routing elements. In the preferred embodiment the enable input to the AND function is connected to the input routing element.

Routing Element

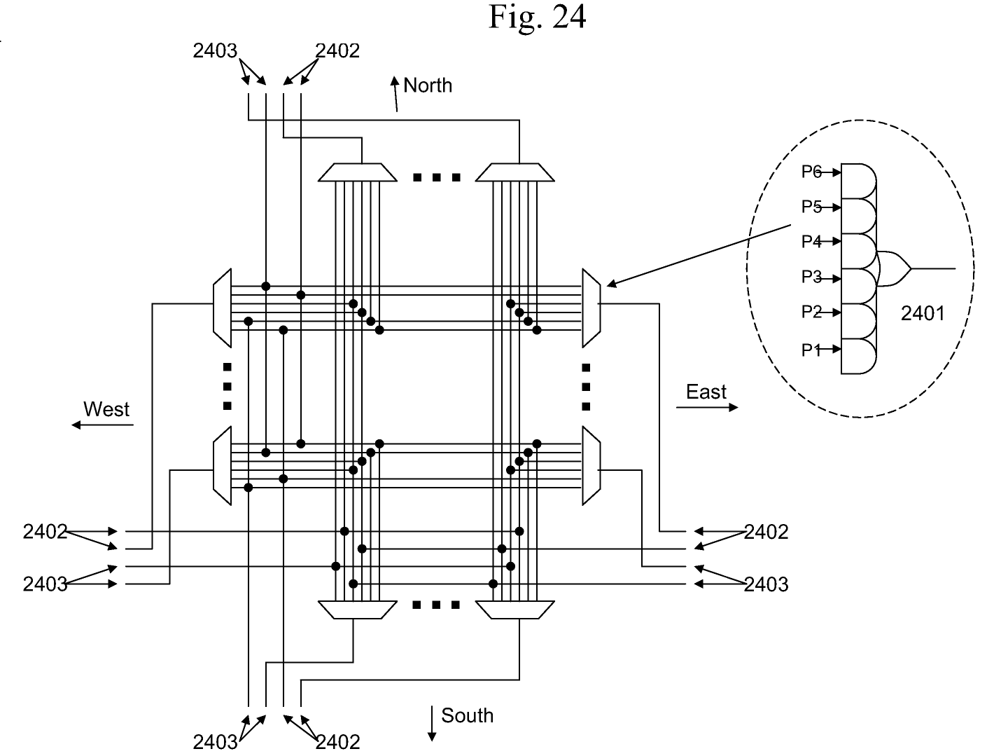

FIG. 24 shows a routing element that incorporates OR functions that can be used in a hierarchical routing system. This routing element consists of eight programmable OR functions (2401). Signals can enter the routing element from any of four directions. For convenience, these directions are referred to as “North, South, East, and West. Signals entering the routing element from the North, East, of South on either of two inputs e.g. a double or hex line can be ORed together and propagated to the west on either of two outputs. Which signals contribute to the OR function is controlled by programming bits.

Application to a RAM Block

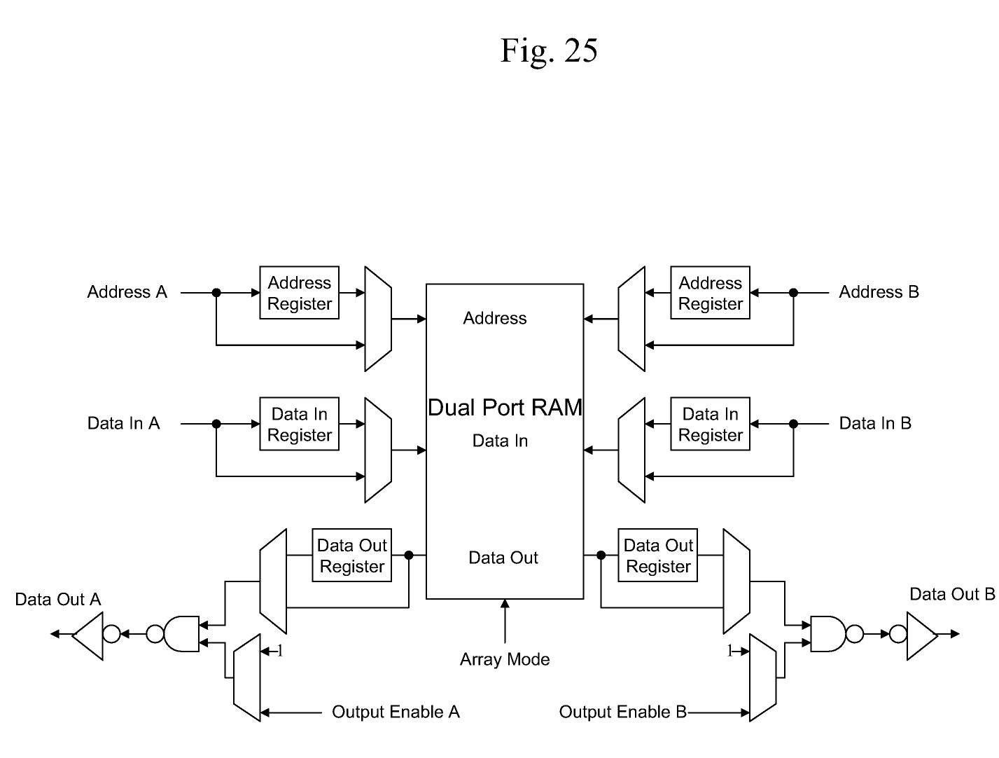

Since the RAM elements in stare of the art FPGAs are frequently connected to high fan in signals such as microprocessor data busses the RAM blocks should also be modified to contain AND based outputs. FIG. 25 illustrates a RAM similar to the Altera Tri matrix RAM and Xilinx Block RAM. The AND function and repeater added to the Data Out circuit enables the use of the improved routing element. The Xilinx Distributed RAM, as described in Xilinx Virtex-4 RAM is implemented in the logic function and can take advantage of the output AND function shown in FIG. 23.

Application to a Processor

The high fan in busses of a microprocessor including the data output bus and address bus for processors that support external bus masters should also incorporate an AND function in the output buffers to take advantage of this invention.

Output Routing

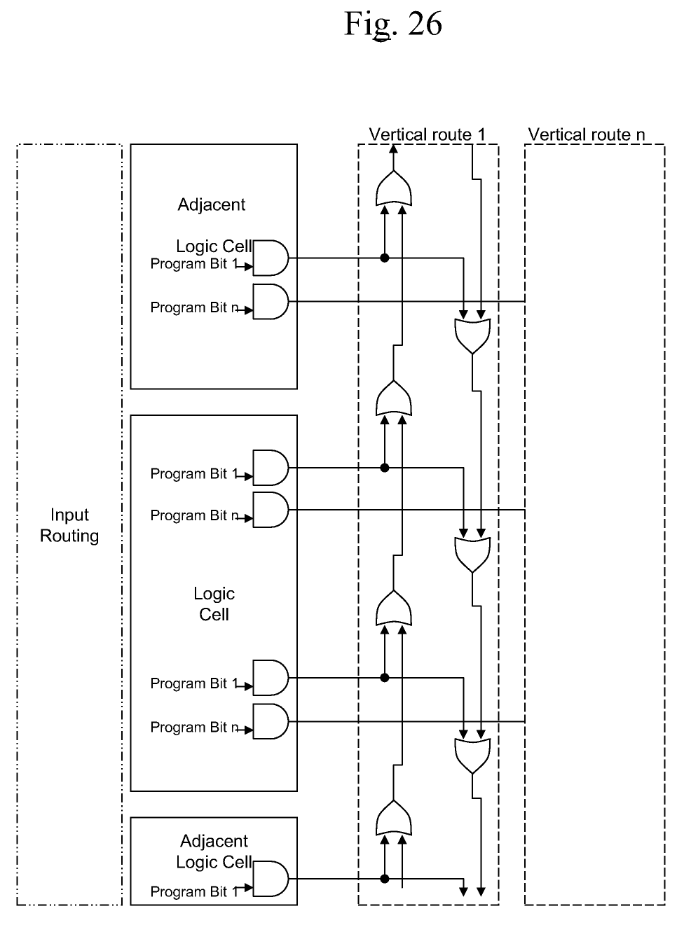

FIG. 26 illustrates the use of an OR function to replace the transfer gates conventionally used to connect the logic functions to the adjacent routing.

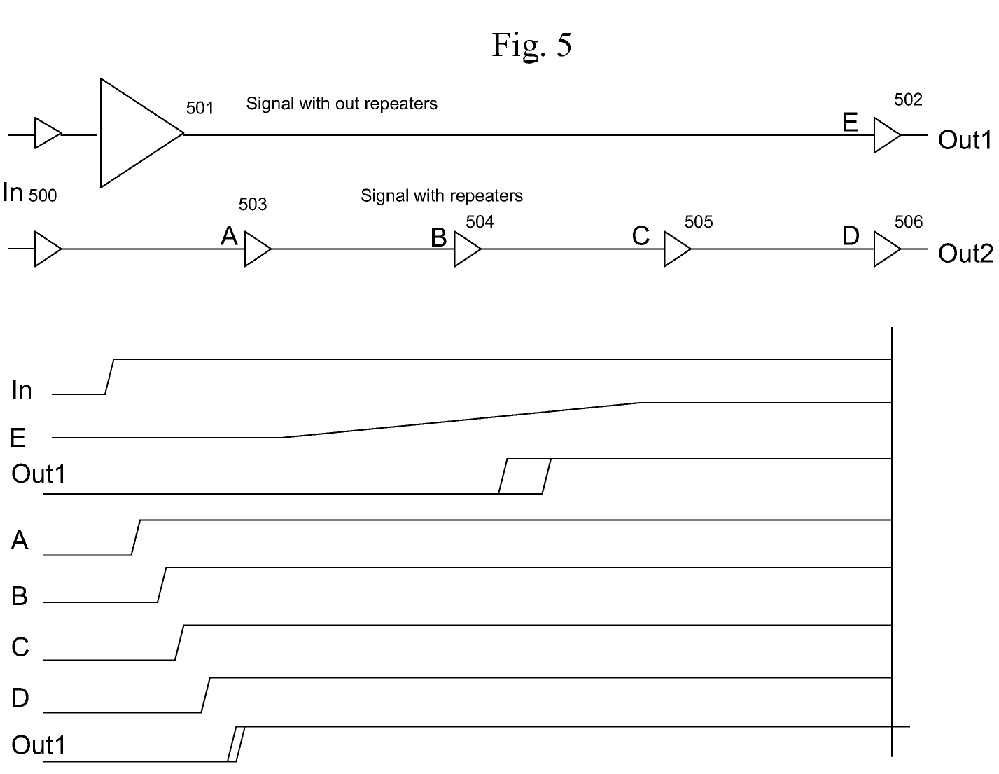

The bi-directional transfer gate and single wire has been replaced by two unidirectional wires and logic gates. In this example timing will be improved over the transfer gate based interconnect due to repeater insertion as shown in FIG. 5. The circuit of FIG. 26 can also be used to interconnect logic elements that are not adjacent i.e. logic elements 2, 3, or 6 rows of columns away.

Application to a Soft IP Core

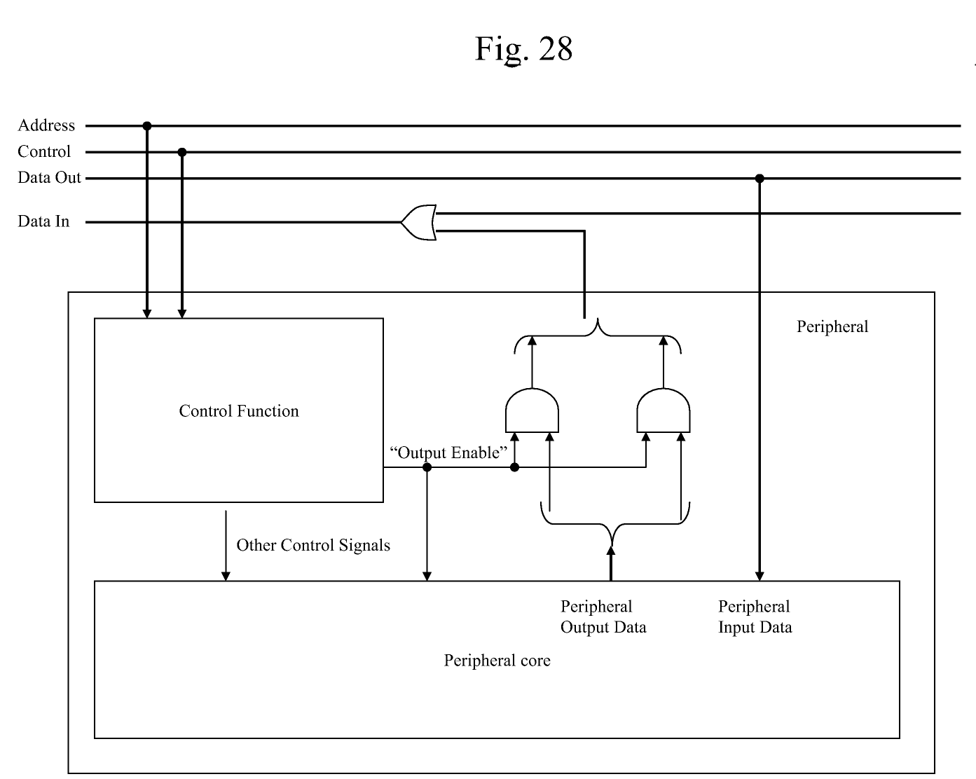

FIG. 28 illustrates a microprocessor peripheral designed to take advantage of the invention. The AND functions used in the Data in connection will be implemented in the AND function in the Logic Elements.

Application to Distributed RAM

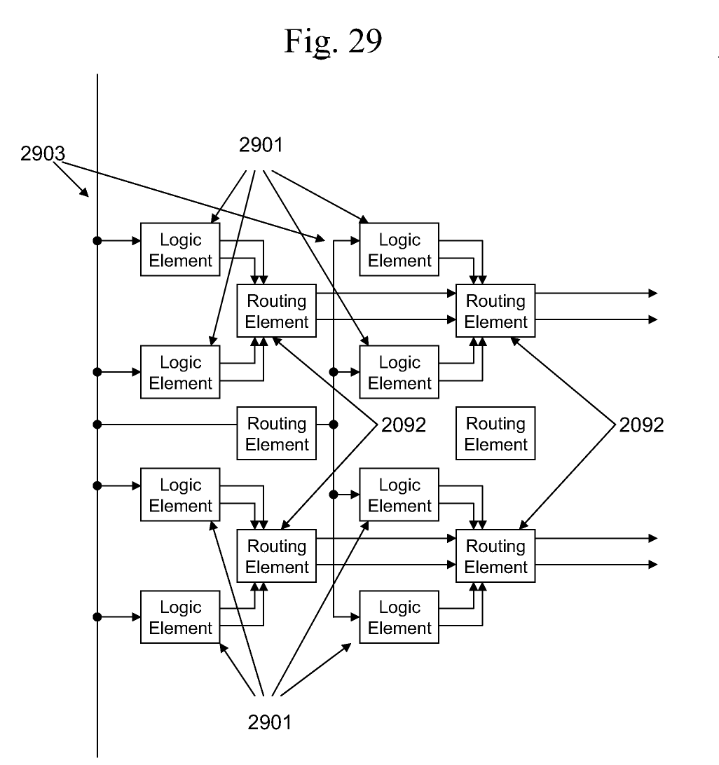

FIG. 29 illustrates the data output routing of a 64 word by 4 bit distributed RAM using logic elements with an AND function in the output (2901) and OR function in the routing element (2902). This use of the invention will result in a more efficient distributed RAM since no additional logic elements are required to interconnect the outputs. Address inputs and “chip select” signals will still be routed conventionally (2903).

No Logic Functions and only one routing channel per output bit are used in this example. This greatly simplifies the interconnection of multiple distributed RAMs into larger arrays. This interconnection is useful in structures such as FIFOs and register files in addition to connection to a microprocessor.

Simplified CAM Implementation

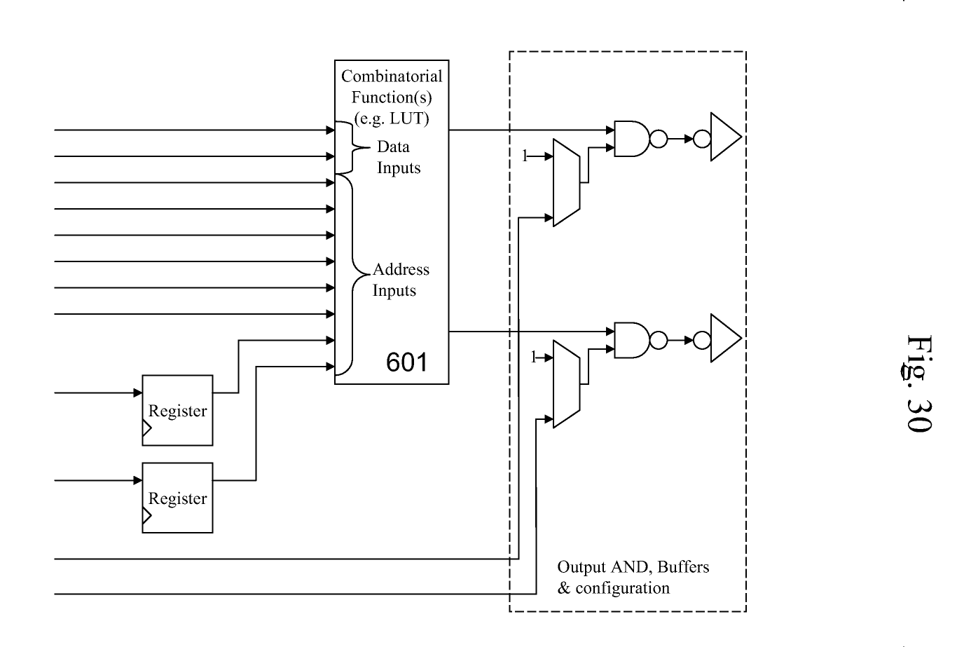

Content Addressable Memories (CAM) consumes extensive logic and routing resources when implemented in current FPGAs. This invention allows for an efficient CAM in an FPGA. The distributed OR function can be used to implement an equivalent to the high fan in “wired AND” function conventionally used to implement match lines in a CAM. To take full advantage of this capability the logic element should allow configuration the interconnections in the logic element as shown in FIG. 30.

Application to ASICs and Structured ASICs

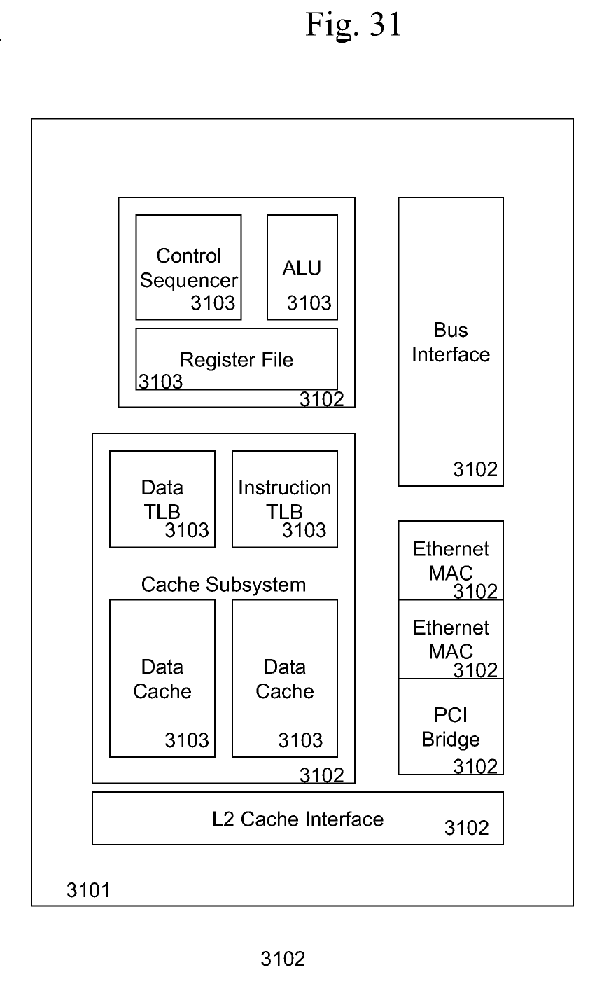

While the description of this invention is focused on the implementation of high fan in functions in FPGAs it will be apparent to one skilled in the art that the same techniques can be applied to ASICs, Structured ASICs and full custom designs. Modern ASIC and full custom designs are hierarchically structured. FIG. 31 illustrates a typical ASIC (in this case a specialized microprocessor incorporating communications interfaces).

Some of these components incorporate a large number of registers and memories connected to wide high fan in busses.

In a typical ASIC design the major components will be assigned so areas on the chip. This process is referred to as floor planning. Floor planning may also assign locations for the connection of specific interface signals. Once floor planning is done low level gates and standard cells that make up the individual components are placed and routed. After the major components have been placed and routed the connections between the major components are routed. Because the connections between major components are long large ASIC designs require “repeater insertion” for high performance (FIG. 5).

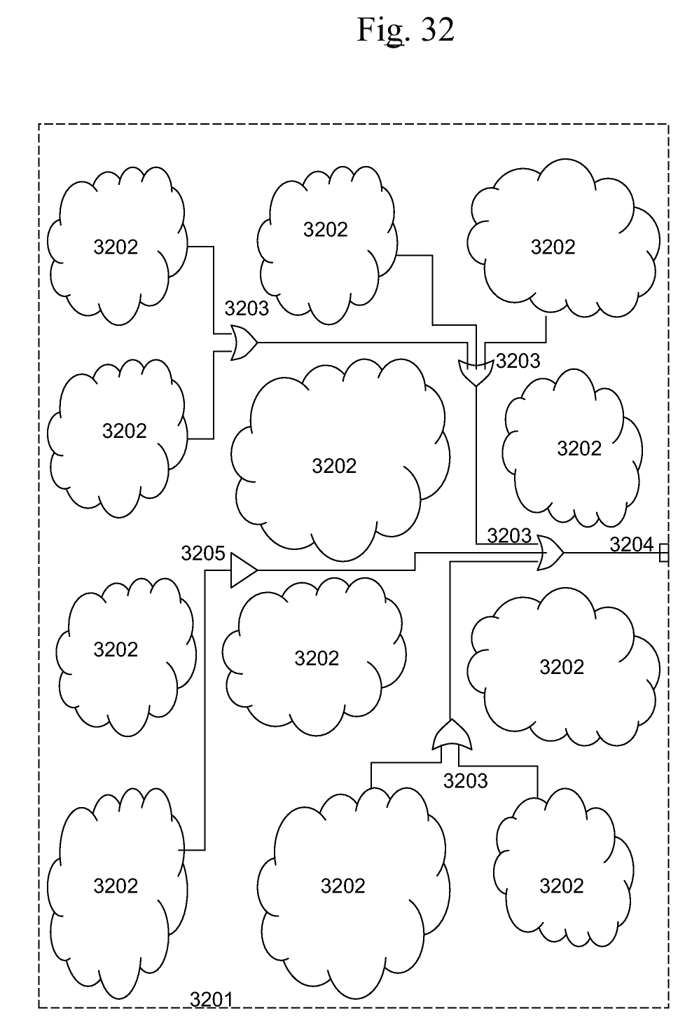

This invention can be applied to internal routing in the major components and the interconnection between the components. Internal to the major components OR functions can be placed at locations where two or more signals that comprise a high fan in network join as shown in FIG. 32.

Software for Routing an FPGA or ASIC

FPGAs and ASICs are typically routed using Automatic Place Route software. APR software typically involves complex routing algorithms that attempt to determine a set of routes for all signals in a design that meets the timing goals specified as “timing constraints” by the user. For high fan-in signals these FPGA routing algorithms can be modified to take advantage of the OR functions in the routing elements as follows:
All of the signals that are part of a high fan in network (the input and output signals of the OR functions) are first routed as though they were a single network containing no logic functions.
The OR function of a routing element where two or more signals from CLBs or other OR functions join to create another output signal in enabled.

For ASICs the OR functions within major blocks can be placed as part of the placement program using conventional methods such as:
Force directed placement
Simulated annealing

The OR functions can also be placed to produce wire equal length or equal delay (wire delay plus gate delay) trees.

Alternatively the OR functions can be placed and routed as part of the routing process similar to repeater insertion. In this case the method described for FPGAs will be used with the additional step of inserting the OR functions where multiple nets join.

The inter-component placement of OR functions and routing can be performed using any of the methods described for ASIC components though performing it as part of routing and repeater insertion is preferred since the OR functions will act as repeaters.

It will be understood that the forgoing is only illustrative of the principles of the invention, and that various modifications can be made by those skilled in the art without departing from the scope and spirit of the invention. For example, the AND and OR functions described herein and in the claims may be implemented by use of NAND/NAND, NOR/NOR or other logical equivalents to implement the disclosed invention and related means and methods. Furthermore, the term “amplifier” includes the use of a “repeater”; and an “ASIC” includes the use of a “structured ASIC”.

What is claimed is:

1. A method for routing signals comprising:
use of a distributed AND function in the logic elements of a FPGA; and
use of a distributed OR function in the routing components of a FPGA.

2. The method of claim 1 using the AND function at the output stage of the logic function.

3. The method of claim 1 using the AND function in the output routing element.

4. The method of claim 1 used as a method of implementing a wide multiplexer and a wide multiplexer's routing in a FPGA.

5. The method of claim 1 connecting one or more inputs of the AND function to the combinatorial logic function in the logic element of an FPGA.

6. The method of claim 1 connecting one or more inputs of the AND function to the input routing element.

7. The method of claim 1 incorporating the AND function in a dedicated RAM or microprocessor.

8. The method of claim 7 incorporating the AND function used in a hard core in a FPGA.

9. The method of claim 1 using the distributed AND and OR functions on a subset of the interconnect.

10. The method of claim 1 connecting the storage elements in FPGA logic elements and the output AND function to implement a binary or ternary CAM cell.

11. The method of claim 10 using the OR function in the routing element as an “as wired AND”.

12. The method of claim 1 wherein the OR function includes the use of an amplifier.

13. A method of implementing a fan-in function and a fan-in function's associated routing in an ASIC comprising:
use of a distributed AND function used in the logic elements and marco cells; and
use of a distributed OR function used in the routing components.

14. A method of assigning a routing attribute to signals that connect to a high fan function comprising:
a) routing the signals as if they were a single signal; and
b) using the signal's attribute to indicate to the place and route tools where to:
1) enable the OR functions in an FPGA;
2) insert an OR function in an ASIC; and
3) replace a repeater with an OR function.

15. The method of claim 14 wherein the initial signal routing is performed using a conventional routing algorithm and the OR function of the routing element of an FPGA or ASIC is enabled in the routing elements where two or more signals are joined together.

16. A device for implementing a multiplexer and the multiplexer's routing in an FPGA, comprising:
a distributed AND function used in the logic elements of the of the FPGA; and
a distributed OR function used in the routing components of the FPGA.

17. The device of claim 16 wherein the AND function is used at the output stage of the logic function.

18. The device of claim 16 wherein the AND function is used in the output routing element.

19. The device of claim 16 wherein one or more inputs of the AND function are connected to the combinatorial logic function in a logic element of a FPGA.
